(19) United States
(12) Patent Application Publication
(10) Pub. No.: US 2025/0226024 A1
(43) Pub. Date: Jul. 10, 2025

(54) SEMICONDUCTOR DEVICE

(71) Applicant: MICRON TECHNOLOGY, INC., BOISE, ID (US)

(72) Inventors: Moe Ishimatsu, Tokyo (JP); Hayato Oishi, Tokyo (JP); Hiroki Hosaka, Sagamihara (JP); Satoru Sugimoto, Sagamihara (JP); Maya Hashimoto, Kawasaki (JP)

(73) Assignee: MICRON TECHNOLOGY, INC., Boise, ID (US)

(21) Appl. No.: 19/000,801

(22) Filed: Dec. 24, 2024

Related U.S. Application Data
(60) Provisional application No. 63/618,556, filed on Jan. 8, 2024.

(51) Int. Cl. G11C 11/4076; H10B 12/00

(52) U.S. Cl. CPC G11C 11/4076; H10B 12/50

(57) ABSTRACT

An example apparatus including a first, second, third, and fourth inverter, each having an input and an output; a first wiring structure including a first wiring portion in an upper wiring layer, the first wiring structure coupled to the input of the first inverter; a second wiring structure including a second wiring portion in the lower wiring layer, the second wiring structure coupled to the output of the first inverter and the input of the second inverter; and a third wiring structure including a third wiring portion in the upper wiring layer, the third wiring structure coupled to the output of the second inverter and the input of the third inverter. The first wiring portion and the second wiring portion partially overlap with each other; and wherein the second wiring portion and the third wiring portion partially overlap with each other.

### CROSS-REFERENCE TO RELATED APPLICATIONS

This application claims the filing benefit of U.S. Provisional Application No. 63/618,556, filed Jan. 8, 2024. This application is incorporated by reference herein in its entirety and for all purposes.

### BACKGROUND

In recent years, as semiconductor devices exemplified by dynamic random access memories (DRAMs) have been further micronized, the operating speed of metal-oxide-semiconductor (MOS) transistors has been increased. Furthermore, since an inverter stage delay amount of an inverter delay circuit comprised of MOS transistors is being reduced, it is necessary to arrange a large number of inverter stages in order to obtain a necessary delay amount. Therefore, if a delay circuit is provided with a large number of inverter stages, an area corresponding to the number of stages is required, resulting in an increase in chip area.

### BRIEF DESCRIPTION OF THE DRAWINGS

FIG. 1 is a plan view showing a schematic configuration of a semiconductor device according to an embodiment;

FIG. 2 is a plan view showing a schematic configuration of the semiconductor device according to the embodiment;

FIG. 3 is a plan view showing a schematic configuration of the semiconductor device according to the embodiment;

FIG. 4 is a longitudinally sectional view showing a schematic configuration of the semiconductor device according to the embodiment;

FIG. 5A to FIG. 5D are plan views showing a schematic configuration of each wiring included in a second layer;

FIG. 6A to FIG. 6G are plan views showing a schematic configuration of each wiring included in a third layer;

FIG. 7 is a circuit diagram of the semiconductor device according to the embodiment; and

FIG. 8 is a circuit diagram of the semiconductor device according to the embodiment.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

A semiconductor device according to an embodiment will be described below with reference to the drawings. In the description of the embodiment, common or related elements, or substantially the same elements are designated by the same reference signs, and the description thereof will be omitted. In the following figures, the dimensions and dimension ratios of the respective parts in each figure do not necessarily match the dimensions and dimension ratios in the embodiment. Furthermore, in the following description, a Y-direction is a direction perpendicular to an X-direction. A Z-direction is a direction perpendicular to an X-Y plane which is a plane of a semiconductor substrate, and is sometimes referred to as a vertical direction.

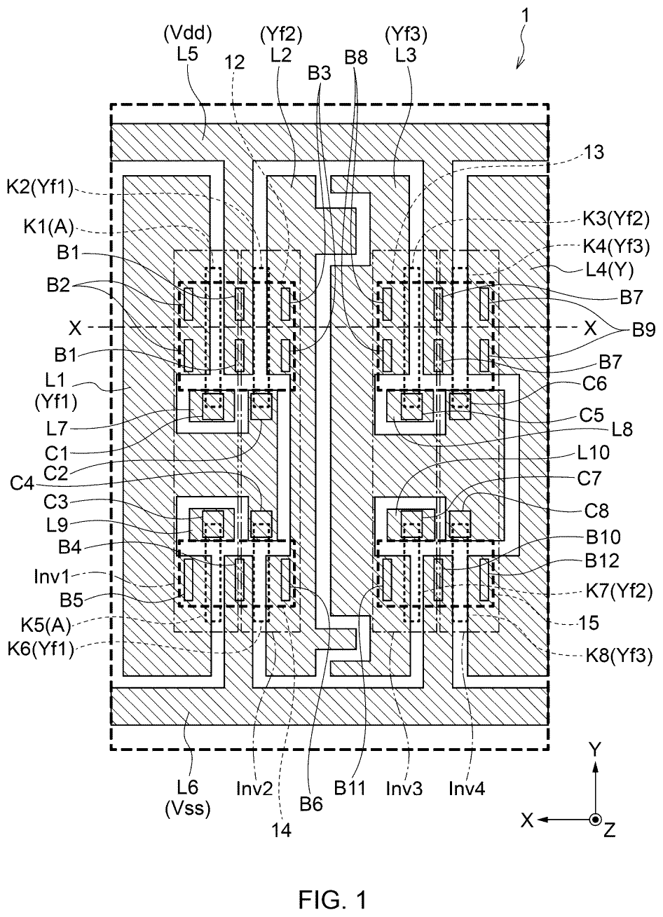

The semiconductor device according to the embodiment will be described below. In the following description, dynamic random access memory (DRAM) will be illustrated as an example. Examples of DRAM include SDRAM (synchronous DRAM), DDR (double data rate) SDRAM, DDR2 (double data rate 2) SDRAM, and DDR3 (double data rate 3) SDRAM. FIG. 1 to FIG. 3 schematically show examples of planar layouts in the same region within a DRAM chip.

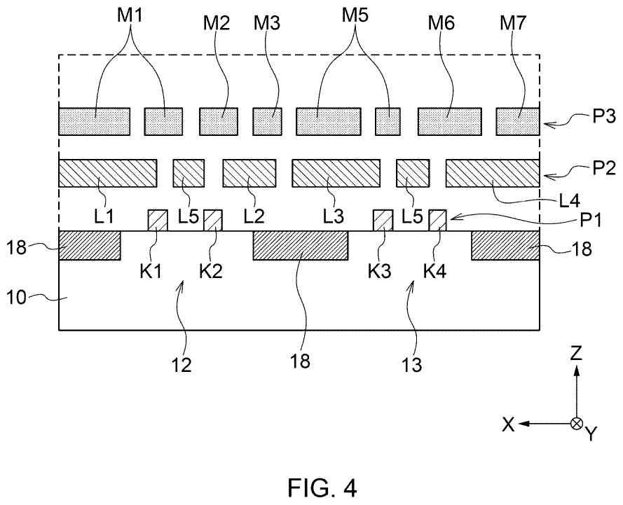

FIG. 4 shows a schematic longitudinally sectional view of the semiconductor device according to the embodiment. FIG. 4 is a longitudinally sectional view of a portion along line X-X in FIG. 1 to FIG. 3.

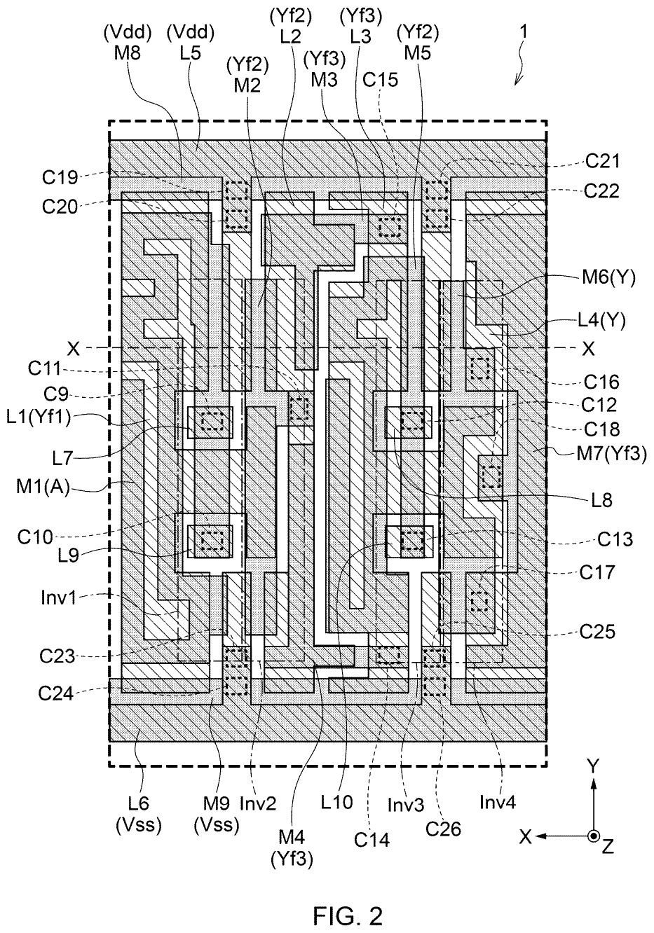

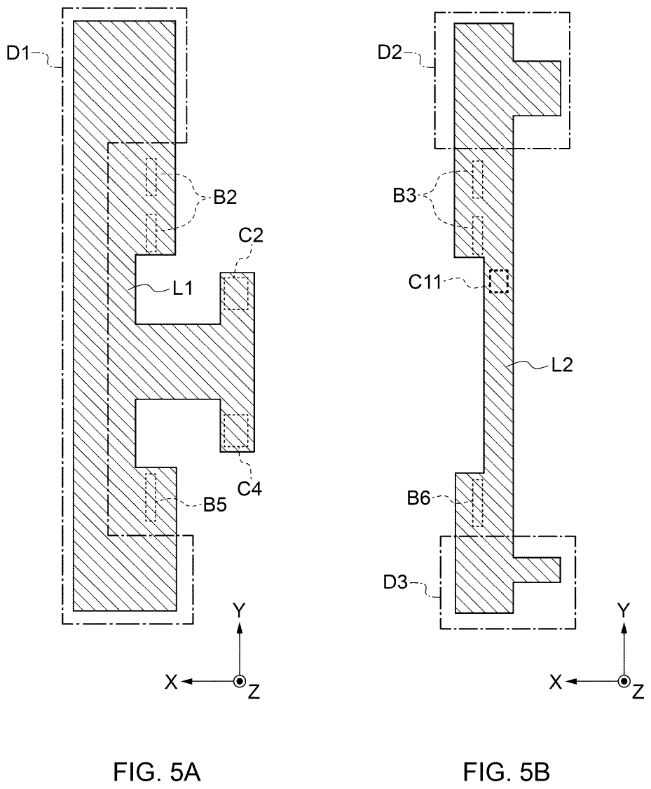

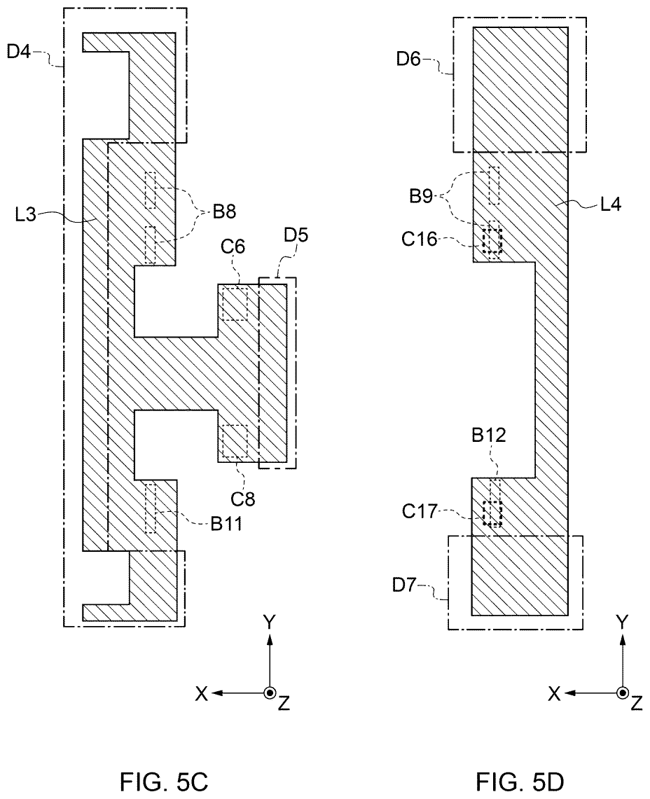

FIG. 5A to FIG. 5D are plan views showing schematic configurations of respective electrodes L1 to L4 included in a second layer P2 shown in FIG. 1, FIG. 2, and FIG. 4.

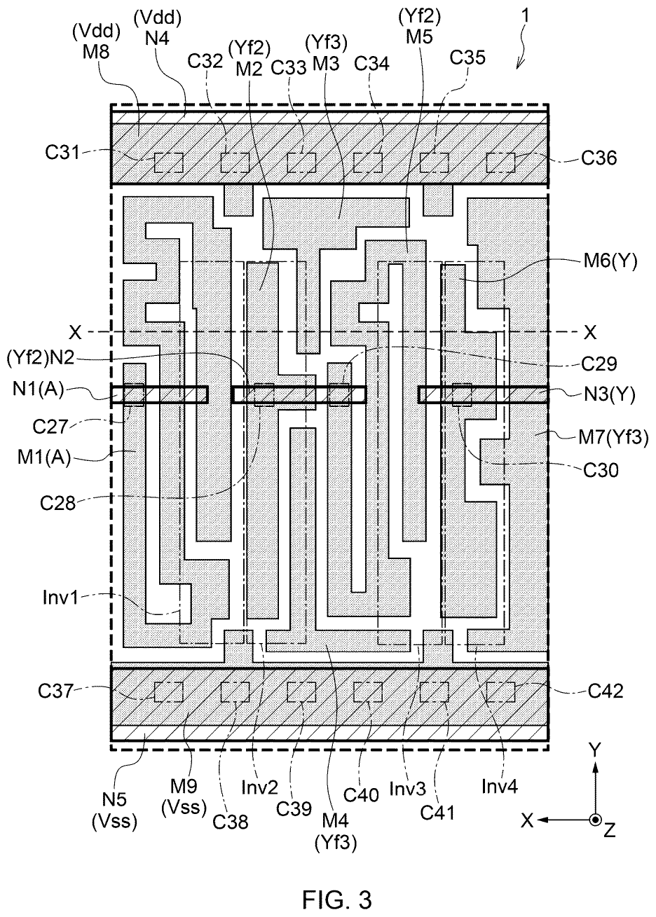

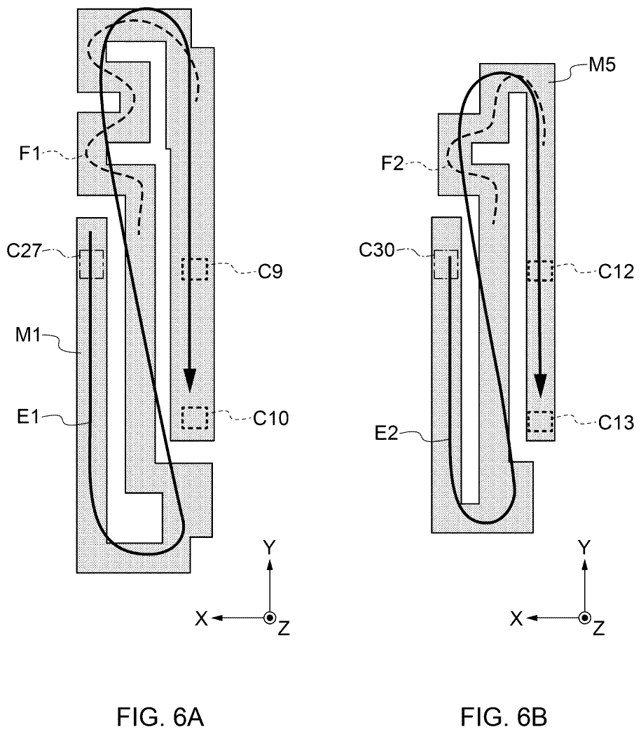

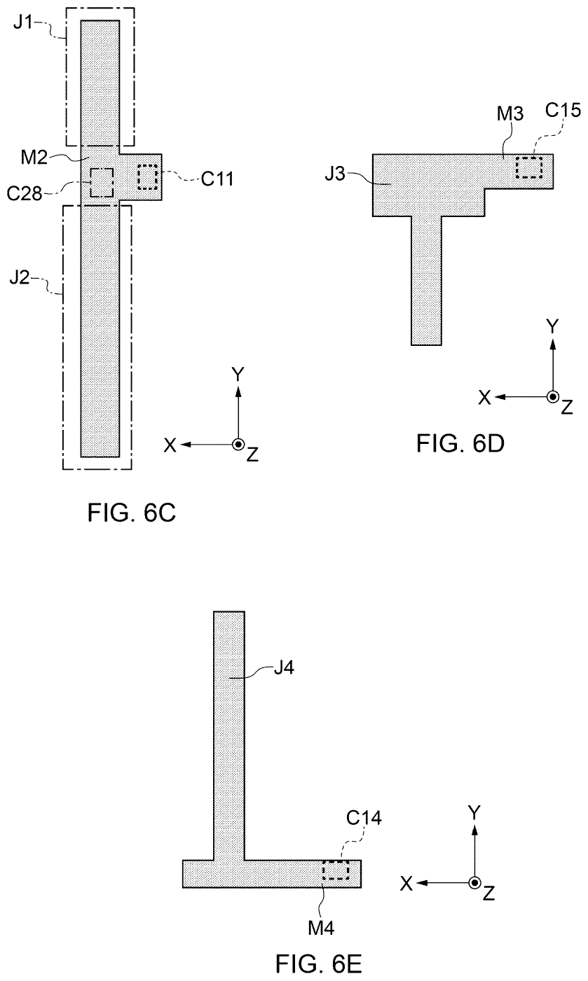

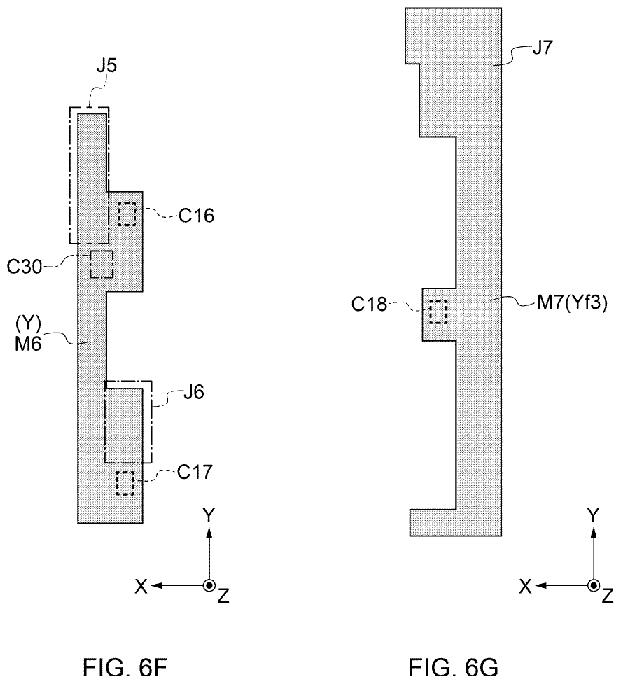

FIG. 6A to FIG. 6G are plan views showing schematic configurations of respective electrodes M1 to M7 included in a third layer P3 shown in FIG. 2, FIG. 3, and FIG. 4.

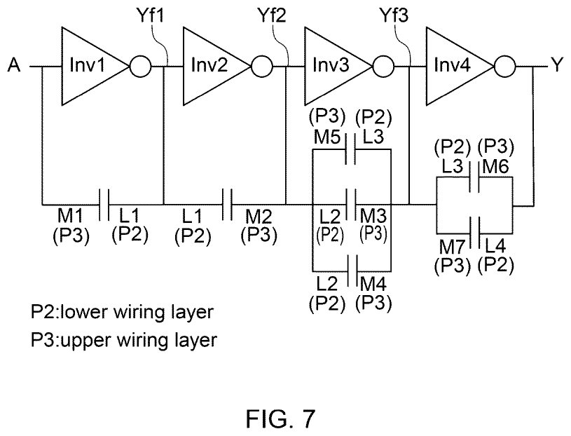

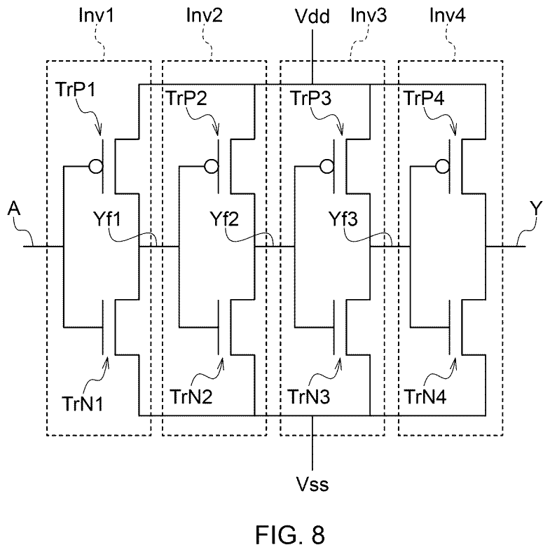

FIG. 7 and FIG. 8 show circuit diagrams of the semiconductor device according to the embodiment. FIG. 7 shows a logical circuit diagram of a delay circuit comprising multi-stage inverter circuits connected in series. Further, FIG. 7 shows a schematic configuration of a capacitor formed by overlapping wirings L1 to L6 and wirings M1 to M7. FIG. 8 shows a circuit diagram in which the delay circuit shown in FIG. 7 is implemented by CMOS (complementary metal oxide semiconductor) transistors.

The semiconductor device according to the embodiment includes a delay circuit comprising CMOS inverters connected in multiple stages (even-numbered stages). For example, as shown in FIG. 7 and FIG. 8, a semiconductor device 1 includes a delay circuit comprising CMOS inverters Inv1 to Inv4 connected in four stages. Each of the CMOS inverters Inv1 to Inv4 includes one N-channel MOS transistor and one P-channel MOS transistor. A first CMOS inverter Inv1 includes a first P-channel transistor TrP1 and a first N-channel transistor TrN1. A second CMOS inverter Inv2 includes a second P-channel transistor TrP2 and a second N-channel transistor TrN2. A third CMOS inverter Inv3 includes a third P-channel transistor TrP3 and a third N-channel transistor TrN3. A fourth CMOS inverter Inv4 includes a fourth P-channel transistor TrP4 and a fourth N-channel transistor TrN4. This delay circuit includes an input line A and an output line Y. The respective CMOS inverters Inv1 to Inv4 are connected to one another through a first node Yf1, a second node Yf2, and a third node Yf3. Note that the input line A and the output line Y are also nodes.

Each of the CMOS inverters Inv1 to Inv4 is achieved by vertically connecting each of the P-channel transistors TrP1 to TrP4 and the corresponding one of the N-channel transistors TrN1 to TrN4 between power supply potentials Vdd and Vss. An input signal of the delay circuit is input to the input line A, and an output signal is output from the output line Y. A positive potential is applied to the power supply potential Vdd, which serves as a source power supply for the P-channel transistors TrP1 to TrP4. A ground potential is applied to the power supply potential Vss, which serves as a source power supply for the N-channel transistors TrN1 to TrN4.

The input signal of the first CMOS inverter Inv1 is input to the input line A. The output signal of the first CMOS inverter Inv1 is output to a first node Yf1, and serves as an input signal to the second CMOS inverter Inv2. The output signal of the second CMOS inverter Inv2 is output to a second node Yf2, and serves as an input signal to the third CMOS inverter Inv3. The output signal of the third CMOS inverter Inv3 is output to a third node Yf3, and serves as an input signal to the fourth CMOS inverter Inv4. The output signal of the fourth CMOS inverter Inv4 is output to the output line Y.

Since the signal input to the input line A is inverted by the first CMOS inverter Inv1, the signal of the input line A has an opposite phase to the signal at the first node Yf1. Since the signal input to the first node Yf1 is inverted by the second CMOS inverter Inv2, the signal at the first node Yf1 has an opposite phase to the signal at the second node Yf2. Since the signal input to the second node Yf2 is inverted by the third CMOS inverter Inv3, the signal at the second node Yf2 has an opposite phase to the signal at the third node Yf3. The output signal of the fourth CMOS inverter Inv4 is output to the output line Y. Since the signal input to the third node Yf3 is inverted by the fourth CMOS inverter Inv4, the signal at the third node Yf3 has an opposite phase to the signal at the output line Y.

As shown in FIG. 1 to FIG. 3, the input line A has a wiring structure including a twelfth wiring N1, a fifth wiring M1, a first P gate electrode K1, and a first N gate electrode K5. The first node Yf1 has a wiring structure including a first wiring L1, a second P gate electrode K2, and a second N gate electrode K6. The second node Yf2 has a wiring structure including a second wiring L2, a sixth wiring M2, a ninth wiring M5, a thirteenth wiring N2, a third P gate electrode K3, and a third N gate electrode K7. The third node Yf3 has a wiring structure including a third wiring L3, a seventh wiring M3, an eighth wiring M4, an eleventh wiring M7, a fourth P gate electrode K4, and a fourth N gate electrode K8.

As shown in FIG. 4, the semiconductor device 1 according to the embodiment includes conductors included in the first layer P1, the second layer P2, and the third layer P3 in order from the one closest to the semiconductor substrate 10. The twelfth wiring N1, the thirteenth wiring N2, the fourteenth wiring N3, a fifth power supply wiring N4, and a sixth power supply wiring N5 shown in FIG. 3 are included in a fourth layer P4. The fourth layer P4 corresponds to an upper layer of the third layer P3. The first layer P1, the second layer P2, the third layer P3, and the fourth layer P4 are separately provided as different layers. FIG. 1 shows an example of a planar layout of the first layer P1 and the second layer P2. FIG. 2 shows an example of a planar layout of the second layer P2 and the third layer P3. FIG. 3 shows an example of a planar layout of the third layer P3 and the fourth layer P4.

As shown in FIG. 1, the semiconductor device 1 includes a first P gate electrode K1 to a fourth P gate electrode K4, and a first N gate electrode K5 to a fourth N gate electrode K8. The gate electrodes K1 to K8 are included in the first layer P1. The semiconductor device 1 includes the first wiring L1, the second wiring L2, the third wiring L3, the fourth wiring L4, the power supply wiring L5 (Vdd), and the power supply wiring L6 (Vss). The wirings L1 to L6 are lower electrodes included in the second layer P2 (lower wiring layer). Each of the wirings L1 to L6 is a wiring portion that serves as a part of each node of the input line A, the first node Yf1, the second node Yf2, the third node Yf3, and the output line Y.

The first P gate electrode K1 and the second P gate electrode K2 are arranged in an active region 12. The third P gate electrode K3 and the fourth P gate electrode K4 are arranged in an active region 13. The first N gate electrode K5 and the second N gate electrode K6 are arranged in an active region 14. The third N gate electrode K7 and the fourth N gate electrode K8 are arranged in an active region 15. As shown in FIG. 4, each of the active regions 12 to 15 is surrounded by an isolation 18 containing an insulator, whereby they are electrically isolated from one another.

A first contact B1 is arranged in the active region 12 between the first P gate electrode K1 and the second P gate electrode K2, and is connected to the first power supply wiring L5 (Vdd). A second contact B2 and a third contact B3 are arranged in the active region 12 on both sides of the first P gate electrode K1 and the second P gate electrode K2. The second contact B2 is connected to the first wiring L1, and the third contact B3 is connected to the second wiring L2.

A seventh contact B7 is arranged in the active region 13 between the third P gate electrode K3 and the fourth P gate electrode K4, and is connected to the first power supply wiring L5 (Vdd). An eighth contact B8 and a ninth contact B9 are arranged in the active region 13 on both sides of the third P gate electrode K3 and the fourth P gate electrode K4. The eighth contact B8 is connected to the third wiring L3, and the ninth contact B9 is connected to the fourth wiring L4.

A fourth contact B4 is arranged in the active region 14 between the first N gate electrode K5 and the second N gate electrode K6, and is connected to the second power supply wiring L6 (Vss). A fifth contact B5 and a sixth contact B6 are arranged in the active region 13 on both sides of the first N gate electrode K5 and the second N gate electrode K6. The fifth contact B5 is connected to the first wiring LI, and the sixth contact B6 is connected to the second wiring L2.

A tenth contact B10 is arranged in the active region 14 between the third N gate electrode K7 and the fourth N gate electrode K8, and is connected to the second power supply wiring L6 (Vss). An eleventh contact B11 and a twelfth contact B12 are arranged in the active region 14 on both sides of the third N gate electrode K7 and the fourth N gate electrode K8. The eleventh contact B11 is connected to the third wiring L3, and the twelfth contact B12 is connected to the fourth wiring L4.

As shown in FIG. 1 and FIG. 8, the first P gate electrode K1 serves as a gate electrode of the first P-channel transistor TrP1. The second P gate electrode K2 serves as a gate electrode of the second P-channel transistor TrP2. The third P gate electrode K3 serves as a gate electrode of the third P-channel transistor TrP3. The fourth P gate electrode K4 serves as a gate electrode of the fourth P-channel transistor TrP4. The first N-gate electrode K5 serves as a gate electrode of the first N-channel transistor TrN1. The second N-gate electrode K6 serves as a gate electrode of the second N-channel transistor TrN2. The third N-gate electrode K7 serves as a gate electrode of the third N-channel transistor TrN3. The fourth N gate electrode K8 serves as a gate electrode of the fourth N channel transistor TrN4.

The first wiring L1 is connected to the second P gate electrode K2 via a gate contact C2, and is connected to the second N gate electrode K6 via the gate contact C4. The third wiring L3 is connected to the fourth P gate electrode K4 via a gate contact C6, and is connected to the fourth N gate electrode K8 via a gate contact C8. A local wiring L7 is connected to the first P gate electrode K1 via a gate contact C1. A local wiring L8 is connected to the third P gate electrode K3 via a gate contact C5. A local wiring L9 is connected to the first N gate electrode K5 via a gate contact C3. A local wiring L10 is connected to the third N gate electrode K7 via a gate contact C7.

In the plan view shown in FIG. 1, a part of the first P gate electrode K1 overlaps the first wiring L1 in a cross-sectional direction, and is adjacent to the first power supply wiring L5. A part of the second P gate electrode K2 is in contact with the first power supply wiring L5 and the second wiring L2. A part of the third P gate electrode K3 overlaps the third wiring L3 in the cross-sectional direction and is in contact with the first power supply wiring L5. A part of the fourth P gate electrode K4 is in contact with the first power supply wiring L5 and the fourth wiring L4. A part of the first N gate electrode K5 overlaps the first wiring L1 in the cross-sectional direction and is in contact with the second power supply wiring L6. A part of the second N gate electrode K6 is in contact with the second power supply wiring L6 and the second wiring L2. A part of the third N gate electrode K7 overlaps the third wiring L3 in the cross-sectional direction and is in contact with the second power supply wiring L6. A part of the fourth N gate electrode K8 is in contact with the second power supply wiring L6 and the fourth wiring L4. In this way, the first layer P1 and the second layer P2 are arranged so as to be partially overlapped with each other in the cross-sectional direction and partially adjacent to each other within an allowable range on the layout, which makes it possible to increase the inter-wiring capacitance between the wiring included in the first layer P1 and the wiring included in the second layer P2.

As shown in FIG. 7 and FIG. 8, the first P gate electrode K1 and the first N gate electrode K5 are connected to the input line A, and the first wiring L1 is connected to the first node Yf1. Therefore, a signal to be applied to each of the first P gate electrode K1 and the first N gate electrode K5 and a signal to be applied to the first wiring L1 are mutually opposite in phase to each other. The potential difference between each of the first P gate electrode K1 and the first N gate electrode K5 and the first wiring L1 increases, so that the inter-wiring capacitance therebetween further increases. Therefore, the signal transmitted through the first P gate electrode K1, the first N gate electrode K5, and the first wiring L1 is further delayed.

The second P gate electrode K2 and the second N gate electrode K6 are connected to the first node Yf1, and the second wiring L2 is connected to the second node Yf2. Therefore, a signal to be applied to each of the second P gate electrode K2 and the second N gate electrode K6 and a signal to be applied to the second wiring L2 are mutually opposite in phase to each other. The potential difference between each of the second P gate electrode K2 and the second N gate electrode K6 and the second wiring L2 increases, so that the inter-wiring capacitance therebetween further increases. Therefore, the signal transmitted through the second P gate electrode K2, the second N gate electrode K6, and the second wiring L2 is further delayed.

The third P gate electrode K3 and the third N gate electrode K7 are connected to the second node Yf2, and the third wiring L3 is connected to the third node Yf3. Therefore, a signal to be applied to the third P gate electrode K3 and the third N gate electrode K7 and a signal to be applied to the third wiring L3 are mutually opposite in phase to each other. The potential difference between each of the third P gate electrode K3 and the third N gate electrode K7 and the third wiring L3 increases, so that the inter-wiring capacitance further increases. Therefore, the signal transmitted through the third P gate electrode K3, the third N gate electrode K7, and the third wiring L3 is further delayed.

The fourth P gate electrode K4 and the fourth N gate electrode K8 are connected to the third node Yf3, and the fourth wiring L4 is connected to the output line Y. Therefore, a signal to be applied to each of the fourth P gate electrode K4 and the fourth N gate electrode K8 and a signal to be applied to the fourth wiring L4 are mutually opposite in phase to each other. The potential difference between each of the fourth P gate electrode K4 and the fourth N gate electrode K8 and the fourth wiring L4 increases, so that the inter-wiring capacitance further increases. Therefore, the signal transmitted through the fourth P gate electrode K4, the fourth N gate electrode K8, and the fourth wiring L4 is further delayed.

As shown in FIG. 2, the semiconductor device 1 includes the fifth wiring M1, the sixth wiring M2, the seventh wiring M3, the eighth wiring M4, the ninth wiring M5, the tenth wiring M6, the eleventh wiring M7, the third power supply wiring M8 (Vdd), and the fourth power supply wiring M9 (Vss). The wirings M1 to M9 are upper electrodes included in the third layer P3 (upper wiring layer). The wirings M1 to M7 are wiring portions serving as parts of the respective nodes of the input line A, the first node Yf1, the second node Yf2, the third node Yf3, and the output line Y.

The fifth wiring M1 is connected to local wirings L7 and L9 through wiring contacts C9 and C10, respectively. The sixth wiring M2 is connected to the second wiring L2 through a wiring contact C11. The seventh wiring M3 is connected to the third wiring L3 through a wiring contact C15. The eighth wiring M4 is connected to the third wiring L3 through a wiring contact C14. The ninth wiring M5 is connected to local wirings L8 and L10 through wiring contacts C12 and C13, respectively. The tenth wiring M6 is connected to the fourth wiring L4 through wiring contacts C16 and C17. The third power supply wiring M8 is connected to the first power supply wiring L5 through wiring contacts C19, C20, C21, and C22. The fourth power supply wiring M9 is connected to the second power supply wiring L6 through wiring contacts C23, C24, C25, and C26.

As shown in FIG. 3, the semiconductor device 1 further includes the twelfth wiring N1, the thirteenth wiring N2, the fourteenth wiring N3, the fifth power supply wiring N4 (Vdd), and the sixth power supply wiring N5 (Vss). The twelfth wiring N1 is connected to the fifth wiring M1 by a wiring contact C27. The thirteenth wiring N2 connects the sixth wiring M2 and the ninth wiring M5 to each other through wiring contacts C28 and C29. The fourteenth wiring N3 is connected to the tenth wiring M6 by a wiring contact C30. The fifth power supply wiring N4 is connected to the third power supply wiring M8 by wiring contacts C31 to C36. The sixth power supply wiring N5 is connected to the fourth power supply wiring M9 by wiring contacts C37 to C42.

Next, the first wiring L1, the second wiring L2, the third wiring L3, and the fourth wiring L4 will be described with reference to FIG. 5A to FIG. 5D.

As shown in FIG. 5A, the first wiring L1 is provided to connect the second contact B2, the fifth contact B5, the gate contact C2, and the gate contact C4. Therefore, it is required for the first wiring L1 only to connect the second contact B2, the fifth contact B5, the gate contact C2, and the gate contact C4 to one another at the shortest distance within a layout-permissible range. However, the first wiring L1 includes a surplus portion D1 that is originally an unnecessary portion. By providing the first wiring L1 with the surplus portion D1, it is possible to increase the overlapping area between the first wiring L1 and the fifth wiring M1 in the Z direction, that is, in the cross-sectional direction, so that the inter-wiring capacitance between the first wiring L1 and the fifth wiring M1 can be increased.

As shown in FIG. 5B, the second wiring L2 is provided to connect the third contact B3, the sixth contact B6, and the wiring contact C11 to one another. Therefore, it is required for the second wiring L2 only to connect the third contact B3, the sixth contact B6, and the wiring contact C11 to one another at the shortest distance within a layout-permissible range. However, the second wiring L2 includes surplus portions D2 and D3 that are originally unnecessary portions. By providing the second wiring L2 with the surplus portions D2 and D3, it is possible to increase the overlapping area between the second wiring L2 and each of the sixth wiring M2, the seventh wiring M3, the eighth wiring M4, the third power supply wiring M8, and the fourth power supply wiring M9 in the Z direction, that is, in the cross-sectional direction, so that the inter-wiring capacitance between the second wiring L2 and each of the sixth wiring M2, the seventh wiring M3, the eighth wiring M4, the third power supply wiring M8, and the fourth power supply wiring M9 can be increased.

As shown in FIG. 5C, the third wiring L3 is provided to connect the eighth contact B8, the eleventh contact B11, the gate contact C6, and the gate contact C8 to one another. Therefore, it is required for the third wiring L3 only to connect the eighth contact B8, the eleventh contact B11, the gate contact C6, and the gate contact C8 to one another at the shortest distance within a layout-permissible range. However, the third wiring L3 includes surplus portions D4 and D5 that are originally unnecessary portions. By providing the third wiring L3 with the surplus portions D4 and D5, it is possible to increase the overlapping area between the third wiring L3 and each of the seventh wiring M3, the eighth wiring M4, the ninth wiring M5, the tenth wiring M6, the third power supply wiring M8, and the fourth power supply wiring M9 in the Z direction, that is, in the cross-sectional direction, so that the inter-wiring capacitance between the third wiring L3 and each of the seventh wiring M3, the eighth wiring M4, the ninth wiring M5, the tenth wiring M6, the third power supply wiring M8, and the fourth power supply wiring M9 can be increased.

As shown in FIG. 5D, the fourth wiring L4 is provided to connect the ninth contact B9, the wiring contact C16, and the wiring contact C17 to one another. Therefore, it is required for the third wiring L3 only to connect the ninth contact B9, the wiring contact C16, and the wiring contact C17 to one another at the shortest distance within a layout-permissible range. However, the fourth wiring L4 includes surplus portions D6 and D7 that are originally unnecessary portions. By providing the fourth wiring L4 with the surplus portions D6 and D7, it is possible to increase the overlapping area between the fourth wiring L4 and each of the tenth wiring M6, the eleventh wiring M7, the third power supply wiring M8, and the fourth power supply wiring M9 in the Z direction, that is, in the cross-sectional direction, so that the inter-wiring capacitance between the fourth wiring L4 and each of the tenth wiring M6, the eleventh wiring M7, the third power supply wiring M8, and the fourth power supply wiring M9 can be increased.

Next, the fifth wiring M1, the sixth wiring M2, the seventh wiring M3, the eighth wiring M4, the ninth wiring M5, the tenth wiring M6, and the eleventh wiring M7 will be described with reference to FIG. 6A to FIG. 6G.

As shown in FIG. 6A, the fifth wiring M1 is provided to connect the wiring contacts C9, C10, and C27 to one another. Therefore, it is required for the fifth wiring M1 only to connect the wiring contacts C9, C10, and C27 to one another at the shortest distance within a layout-permissible range. However, the fifth wiring M1 temporarily extends downward in the Y direction from the wiring contact C27, then turns and extends upward in the opposite direction, further turns downward in the opposite direction, and is connected to the wiring contacts C9 and C10. In other words, the fifth wiring M1 does not directly connect the wiring contacts C9, C10, and C27 to one another, but makes a detour so as to increase the connection distance, so that the fifth wiring M1 has a curved portion E1 which is a redundant portion having an overall meandering shape.

Further, the fifth wiring M1 has a curved portion F1 which is a redundant portion having a locally meandering shape and is shorter in distance than the curved portion E1. As described above, the fifth wiring M1 includes one or more curved portions E1 and F1. The fifth wiring M1 includes the curved portions E1 and F1, so that the distance from the wiring contact C27 to the wiring contacts C9 and C10 is longer. Therefore, a signal transmitted through the fifth wiring M1 is delayed.

Due to the presence of the curved portions E1 and F1, the fifth wiring M1 can have a large overlapping area with the first wiring L1 in the Z direction, that is, in the cross-sectional direction, which makes it possible to increase the inter-wiring capacitance between the fifth wiring M1 and the first wiring L1. Therefore, a signal transmitted through the first wiring L1 and the fifth wiring M1 are delayed.

Further, as shown in FIG. 2, FIG. 4, and FIG. 7, the fifth wiring M1 partially overlaps the first wiring L1 in the Z direction, that is, in the cross-sectional direction to form a capacitor. As shown in FIG. 1, FIG. 7, and FIG. 8, the first wiring L1 is connected to the first node Yf1 by the second contact B2. Signals to be applied to the fifth wiring M1 and the first wiring L1 have mutually opposite to each other in phase. Since the potential difference between the fifth wiring M1 and the first wiring L1 increases, so that the inter-wiring capacitance further increases. Therefore, a signal transmitted through the first wiring L1 and the fifth wiring M1 is further delayed.

As shown in FIG. 6B, the ninth wiring M5 is provided to connect the wiring contacts C12, C13, and C30 to one another. Therefore, the ninth wiring M5 is required only to connect the wiring contacts C12, C13, and C30 to one another at the shortest distance within a layout-permissible range. However, the ninth wiring M5 temporarily extends downward in the Y direction from the wiring contact C30, then turns and extends upward in the opposite direction, further turns downward in the opposite direction, and is connected to the wiring contacts C12 and C13. In other words, the ninth wiring M5 does not directly connect the wiring contacts C30, C12, and C13 to one another, but makes a detour to increase the connection distance, so that the ninth wiring M5 has a curved portion E2 which is a redundant portion having an overall meandering shape.

Further, the ninth wiring M5 includes a curved portion F2 which is a redundant portion having a locally meandering shape and is shorter in distance than the curved portion E2. As described above, the ninth wiring M5 includes one or more curved portions E2 and F2. The ninth wiring M5 includes the curved portions E2 and F2, so that the distance from the wiring contact C30 to the wiring contacts C12 and C13 is longer. Therefore, a signal transmitted through the ninth wiring M5 are delayed.

Due to the presence of the curved portions E2 and F2, the ninth wiring M5 can have a large overlapping area with the third wiring L3 in the Z direction, that is, in the cross-sectional direction. Therefore, the inter-wiring capacitance between the ninth wiring M5 and the third wiring L3 can be increased, so that a signal transmitted through the third wiring L3 and the ninth wiring M5 is delayed.

Further, as shown in FIG. 2, FIG. 4, and FIG. 7, the ninth wiring M5 partially overlaps the third wiring L3 in the Z direction, that is, in the cross-sectional direction to form a capacitor. As shown in FIG. 1, FIG. 7, and FIG. 8, the third wiring L3 is connected to the third node Yf3 by the eighth contact B8 and the eleventh contact B11. Signals to be applied to the ninth wiring M5 and the third wiring L3 are opposite in phase to each other. Since the potential difference between the ninth wiring M5 and the third wiring L3 increases, the inter-wiring capacitance further increases. Therefore, a signal transmitted through the third wiring L3 and the ninth wiring M5 is further delayed.

As shown in FIG. 6C, the sixth wiring M2 is provided to connect the wiring contacts C11 and C28 to each other. Therefore, the sixth wiring M2 is required only to connect the wiring contacts C11 and C28 to each other at the shortest distance within a layout-permissible range. However, the sixth wiring M2 includes surplus portions J1 and J2 serving as regions that do not participate in the connection between the wiring contacts C11 and the wiring contacts C28. By providing the surplus portions J1 and J2, the sixth wiring M2 partially overlaps the first wiring L1, the first power supply wiring L5, and the second power supply wiring L6 in the Z direction, that is, in the cross-sectional direction to form a capacitor. FIG. 7 shows a capacitor comprising the sixth wiring M2 and the first wiring L1. Therefore, the inter-wiring capacitance between the first wiring L1 and the sixth wiring M2 increases, so that a signal transmitted through the first wiring L1 and the sixth wiring M2 is delayed.

As shown in FIG. 1, FIG. 2, FIG. 7, and FIG. 8, the sixth wiring M2 is connected to the second wiring L2, that is, the second node Yf2 by the wiring contact C11. The first wiring L1 is connected to the first node Yf1. Signals to be applied to the sixth wiring M2 and the first wiring L1 are opposite in phase to each other. The potential difference between the sixth wiring M2 and the first wiring L1 increases, so that the inter-wiring capacitance further increases. Therefore, a signal transmitted through the sixth wiring M2 and the first wiring L1 is further delayed.

As shown in FIG. 6D and FIG. 2, the seventh wiring M3 is connected to the third wiring L3 by the wiring contact C15, but is not connected to any other wiring. The seventh wiring M3 is connected to the third node Yf3 and forms a part of the third node Yf3. The seventh wiring M3 is a surplus portion J3 that does not function as a wiring for connecting any wirings to each other. The seventh wiring M3 is provided to increase the inter-wiring capacitance.

As shown in FIG. 6E and FIG. 2, the eighth wiring M4 is connected to the third wiring L3 by the wiring contact C14, but is not connected to any other wiring. The eighth wiring M4 is connected to the third node Yf3 and serves as a part of the third node Yf3. The eighth wiring M4 is a surplus portion J4 that does not function as a wiring for connecting any wirings to each other. The eighth wiring M4 is provided to increase the inter-wiring capacitance.

The seventh wiring M3 and the eighth wiring M4 partially overlap the second wiring L2, the first power supply wiring L5, and the second power supply wiring L6 in the Z direction, that is, in the cross-sectional direction to form a capacitor. FIG. 7 shows a capacitor comprising the seventh wiring M3, the eighth wiring M4, and the second wiring L2 (Yf2). Therefore, the inter-wiring capacitance between the seventh wiring M3 and the eighth wiring M4 increases, so that a signal transmitted through a wiring connected to the seventh wiring M3 and the eighth wiring M4 is delayed. As described above, the seventh wiring M3 and the eighth wiring M4 are connected to the third node Yf3. The second wiring L2 is connected to the second node Yf2. Signals to be applied to each of the seventh wiring M3 and the eighth wiring M4 and the second wiring L2 are mutually opposite in phase to each other. The potential difference between each of the seventh wiring M3 and the eighth wiring M4 and the second wiring L2 increases, so that the inter-wiring capacitance further increases. Therefore, a signal transmitted through the third wiring L3 and the second wiring L2 to which the seventh wiring M3 and the eighth wiring M4 are connected is further delayed.

As shown in FIG. 6F and FIG. 2, the tenth wiring M6 is provided to connect the wiring contacts C16, C17, and C30 to one another. Therefore, the tenth wiring M6 is required only to connect the wiring contacts C16, C17, and C30 to one another at the shortest distance within a layout-permissible range. However, the tenth wiring M6 includes surplus portions J5 and J6 as regions that do not participate in the connection of the wiring contacts C16, C17, and C30. By providing the surplus portions J5 and J6, the tenth wiring M6 partially overlaps the third wiring L3, the first power supply wiring L5, and the second power supply wiring L6 in the Z direction to form a capacitor. FIG. 7 shows a capacitor comprising the tenth wiring M6 and the third wiring L3. Therefore, the inter-wiring capacitance between the third wiring L3 and the tenth wiring M6 increases, so that a signal transmitted through the third wiring L3 and the tenth wiring M6 is delayed.

As shown in FIG. 1, FIG. 2, FIG. 7, and FIG. 8, the tenth wiring M6 is connected to the fourth wiring L4 through the wiring contacts C16 and C17. As shown in FIG. 3, the tenth wiring M6 is connected to the output line Y through the wiring contact C30. The third wiring L3 is connected to the eighth contact B8 and the eleventh contact B11, and is connected to the output of the third CMOS inverter Inv3, that is, the third node Yf3. The third node Yf3 serves as an input to the fourth CMOS inverter Inv4, and the output line Y serves as an output of the fourth CMOS inverter Inv4. Therefore, since a signal input to the fourth CMOS inverter Inv4 is inverted, signals to be applied to the tenth wiring M6 and the third wiring L3 are opposite in phase to each other. The potential difference between the tenth wiring M6 and the third wiring L3 increases, so that the inter-wiring capacitance further increases. Therefore, a signal transmitted through the third wiring L3 and the tenth wiring M6 is further delayed.

As shown in FIG. 6G and FIG. 2, the eleventh wiring M7 is connected to the third wiring L3 by the wiring contact C18, but it is not connected to anything else. The eleventh wiring M7 is connected to the third node Yf3, and serves as a part of the third node Yf3. The eleventh wiring M7 is a surplus portion J7 that does not function as a wiring for connecting any wirings. The eleventh wiring M7 is provided to increase the inter-wiring capacitance as described later. The eleventh wiring M7 is connected to the fourth wiring L4, that is, the third node Yf3 by the wiring contact C18.

The eleventh wiring M7 partially overlaps the fourth wiring L4, the first power supply wiring L5, and the second power supply wiring L6 in the Z direction, that is, in the cross-sectional direction to form a capacitor. FIG. 7 shows a capacitor comprising the fourth wiring L4 and the eleventh wiring M7. Therefore, the inter-wiring capacitance between the fourth wiring L4 and the eleventh wiring M7 increases, so that a signal transmitted through a wiring connected to the fourth wiring L4 and the eleventh wiring M7 is delayed. As described above, the eleventh wiring M7 is connected to the third node Yf3. The fourth wiring L4 is connected to the output line Y. Signals to be applied to the fourth wiring L4 and the eleventh wiring M7 are opposite in phase to each other. The potential difference between the eleventh wiring M7 and the fourth wiring L4 increases, so that the inter-wiring capacitance further increases. Therefore, a signal transmitted through the third wiring L3 and the fourth wiring L4 to which the eleventh wiring M7 is connected is further delayed.

As described above, the semiconductor device 1 according to the embodiment includes the delay circuit comprising the inverters Inv1 to Inv4. The semiconductor device 1 includes the wirings L1 to L4 and M1 to M7. By providing the surplus portions D1 to D7 and the surplus portions J1 to J7 for any of the wirings L1 to L6 and M1 to M7, the capacitance of the wirings can be increased. Moreover, by providing the curved portions E1, E2, F1, and F2 for any of the wirings L1 to L6 and M1 to M7, the lengths of the wirings can be increased. These make it possible to increase the delay time of the delay circuit without increasing the number of stages of the delay circuit and increasing the area occupied by the delay circuit. Note that the semiconductor device 1 according to the embodiment is shown to provide an example in which each of the fifth wiring M1 and the ninth wiring M5 includes the curved portions E1, F1 or E2, F2, but the present invention is not limited to this example. Any one of the fifth wiring M1 and the ninth wiring M5 may include the curved portion E1 or E2. Alternatively, any one of the fifth wiring M1 or the ninth wiring M5 may include the curved portion F1 or F2.

As described above, the semiconductor device according to the embodiment has been described by exemplifying DRAM. However, this is just one example, and is not intended to be limited to DRAM. The present invention may be applied to memory devices other than DRAM, such as SRAM (static random access memory), Flash Memory, EPROM (erasable programmable read only memory), MRAM (magnetoresistive random access memory), and PRAM (phase-change memory), ReRAM (resistance random access memory), and FeRAM (ferroelectric random access memory) as the semiconductor device. Further, the present invention may be applied to devices other than memories, for example, various logic ICs such as a microprocessor, logic IC, CPU (central processing unit), MPU (micro-processing unit), and ASIC (application specific integrated circuit).

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus, comprising:
at least first, second and third inverters, each of the first, second and third inverters having an input and an output;
a first wiring structure including a first wiring portion in an upper wiring layer, the first wiring structure coupled to the input of the first inverter;
a second wiring structure including a second wiring portion in a lower wiring layer, the second wiring structure coupled to the output of the first inverter and the input of the second inverter; and
a third wiring structure including a third wiring portion in the upper wiring layer, the third wiring structure coupled to the output of the second inverter and the input of the third inverter;
wherein the first wiring portion in the upper wiring layer of the first wiring structure and the second wiring portion in the lower wiring layer of the second wiring structure partially overlap with each other; and
wherein the second wiring portion in the lower wiring layer of the second wiring structure and the third wiring portion in the upper wiring layer of the third wiring structure partially overlap with each other.

2. The apparatus of claim 1, wherein the third wiring structure further includes a fourth wiring portion, the apparatus further comprising:
a fourth inverter having an input and an output; and
a fourth wiring structure including a fifth wiring portion in the lower wiring layer, the fourth wiring structure coupled to the output of the third inverter and the input of the fourth inverter;
wherein the fourth wiring portion and the fifth wiring portion partially overlap with each other.

3. The apparatus of claim 2, further comprising:
a fifth wiring structure including a sixth wiring portion in the upper wiring layer, the fifth wiring structure coupled to the output of the fourth inverter,
wherein the fifth wiring portion and the sixth wiring portion partially overlap with each other.

4. The apparatus of claim 2,
wherein the third wiring structure further includes a seventh wiring portion in the lower wiring layer;
wherein the fourth wiring structure further includes an eighth wiring portion in the upper wiring layer;
wherein the seventh wiring portion and the eighth wiring portion partially overlap with each other.

5. The apparatus of claim 4,
wherein the fourth wiring structure further includes a ninth wiring portion in the upper wiring layer; and
wherein the seventh wiring portion and the ninth wiring portion partially overlap with each other.

6. The apparatus of claim 3,
wherein the fourth wiring structure further includes a tenth wiring portion in the upper wiring layer;
wherein the fifth wiring structure further includes an eleventh wiring portion in the lower wiring layer; and
wherein the tenth wiring portion and the eleventh wiring portion partially overlap with each other.

7. The apparatus of claim 5, further comprising:
a fifth wiring structure including a sixth wiring portion in the upper wiring layer coupled to the output of the fourth inverter,
wherein the fifth wiring portion and the sixth wiring portion partially overlap with each other.

8. The apparatus of claim 7,
wherein the fourth wiring structure further includes a tenth wiring portion in the upper wiring layer;
wherein the fifth wiring structure further includes an eleventh wiring portion in the lower wiring layer; and
wherein the tenth wiring portion and the eleventh wiring portion partially overlap with each other.

9. The apparatus of claim 2, wherein at least one of the first wiring portion and the fourth wiring portion comprises one or more curved portions.

10. The apparatus of claim 9, wherein the one or more curved portions includes a short-length curved portion and a long-length curved portion.

11. An apparatus, comprising:
a multi-stage inverter delay circuit including at least one inverter circuit, the inverter circuit including an input signal line structure at which an input signal is received and an output signal line structure at which an output signal is output;
wherein the input signal line structure includes a first wiring portion in an upper wiring layer and the first wiring portion has a plurality of curved portions; and
wherein the output signal line structure includes a second wiring portion in a lower wiring layer; and
wherein the first wiring portion and the second wiring portion partially overlap with each other.

12. An apparatus, comprising:
a first inverter coupled between a first node and a second node;
a first capacitor including a first electrode coupled to the first node and a second electrode coupled to the second node;
a second inverter coupled between the second node and a third node; and
a second capacitor including a third electrode coupled to the second node and a fourth electrode coupled to the third node;
wherein the first electrode of the first capacitor comprises a first wiring in an upper wiring layer;
wherein the second electrode of the first capacitor comprises a second wiring in a lower wiring layer;
wherein the third electrode of the second capacitor comprises a third wiring in the lower wiring layer; and
wherein the fourth electrode of the second capacitor comprises a fourth wiring in the upper wiring layer.

13. The apparatus of claim 12, further comprising:
a third inverter coupled between the third node and a fourth node;
a third capacitor including a fifth electrode coupled to the third node and a sixth electrode coupled to the fourth node;
wherein the fifth electrode of the third capacitor comprises a fifth wiring in the upper wiring layer; and
wherein the sixth electrode of the third capacitor comprises a sixth wiring in the lower wiring layer.

14. The apparatus of claim 13, further comprising:
a fourth capacitor including a seventh electrode coupled to the third node and an eighth electrode coupled to the fourth node;
wherein the seventh electrode of the fourth capacitor comprises a seventh wiring in the lower wiring layer; and
wherein the eighth electrode of the fourth capacitor comprises an eighth wiring in the upper wiring layer.

15. The apparatus of claim 14, further comprising:
a fifth capacitor including a ninth electrode coupled to the third node and a tenth electrode coupled to the fourth node;
wherein the ninth electrode of the fifth capacitor comprises a ninth wiring in the lower wiring layer; and
wherein the tenth electrode of the fifth capacitor comprises a tenth wiring in the upper wiring layer.

16. The apparatus of claim 13, further comprising:
a fourth inverter coupled between the fourth node and a fifth node;
a sixth capacitor including an eleventh electrode coupled to the fourth node and a twelfth electrode coupled to the fifth node;
wherein the eleventh electrode of the fourth capacitor comprises an eleventh wiring in the lower wiring layer; and
wherein the twelfth electrode of the sixth capacitor comprises a twelfth wiring in the upper wiring layer.

17. The apparatus of claim 14, further comprising:
a fourth inverter coupled between the fourth node and a fifth node;
a sixth capacitor including an eleventh electrode coupled to the fourth node and a twelfth electrode coupled to the fifth node;
wherein the eleventh electrode of the fourth capacitor comprises an eleventh wiring in the lower wiring layer; and
wherein the twelfth electrode of the sixth capacitor comprises a twelfth wiring in the upper wiring layer.

18. The apparatus of claim 15, further comprising:
a fourth inverter coupled between the fourth node and a fifth node;
a sixth capacitor including an eleventh electrode coupled to the fourth node and a twelfth electrode coupled to the fifth node;
wherein the eleventh electrode of the fourth capacitor comprises an eleventh wiring in the lower wiring layer; and
wherein the twelfth electrode of the sixth capacitor comprises a twelfth wiring in the upper wiring layer.

19. The apparatus of claim 17, further comprising:
a fourth capacitor including a thirteenth electrode coupled to the fourth node and a fourteenth electrode coupled to the fifth node;
wherein the thirteenth electrode of the fourth capacitor comprises a thirteenth wiring in the upper wiring layer; and
wherein the fourteenth electrode of the fourth capacitor comprises a fourteenth wiring in the lower wiring layer.

20. The apparatus of claim 18, further comprising:
a seventh capacitor including a thirteenth electrode coupled to the fourth node and a fourteenth electrode coupled to the fifth node;
wherein the thirteenth electrode of the seventh capacitor comprises a thirteenth wiring in the upper wiring layer, and
wherein the fourteenth electrode of the seventh capacitor comprises a fourteenth wiring in the lower wiring layer.
